(19) United States
(12) Patent Application Publication
(10) Pub. No.: US 2007/0279716 A1
(43) Pub. Date: Dec. 6, 2007

(54) Process method of image data for liquid crystal display

(75) Inventors: Chih-Lei Wu, Padeh City (TW); Kuan-Hung Liu, Padeh City (TW)

Correspondence Address: BIRCH STEWART KOLASCH & BIRCH, PO BOX 747, FALLS CHURCH, VA, 22040-0747, US

(73) Assignee: CHUNGHWA PICTURE TUBES, LTD, Padeh City (TW)

(21) Appl. No.: 11/445,278

(22) Filed: Jun. 2, 2006

(51) Int. Cl. G03F 3/08

(52) U.S. Cl. 358/519; 358/3.01

(57) ABSTRACT

A processing method of dynamic contrast correction is applied to the process of an image display on a liquid crystal display. One or more threshold conditions are configured for analyzing and filtering the image data. The filtered image data is processed with the suitable contrast intensities to enhance the image displayed more natural.

### BACKGROUND OF THE INVENTION

1. Field of the Invention

The present invention relates to a method of gamma correction, and more especially, to a method of adaptive contrast correction and system thereof.

2. Background of the Related Art

A gray scale correction method called “gamma correction” has normally been carried out on a video luminance signal. This is a correction performed on a luminance signal using a gamma correction curve in accordance with the signal level thereof. The gamma correction is performed if the level of a luminance signal is equal to or greater than a predetermined value, which is referred to as a “correction start point”. As is often the case with the prior art, the same correction start point is used for any luminance signal. Also, even if the correction start point is changed according to the average of a luminance signal, for example, the correction quantity is obtained only from the difference between the value of the luminance signal and the correction start point.

However, the characteristic value (e.g., maximum or average value) of a video luminance signal is greatly changeable from frame to frame. Accordingly, the correction quantity should be changed on a frame-by-frame basis even if a luminance signal with the same value is to be processed. For that reason, the gray scale correction could not be performed appropriately because the correction quantity has been obtained by using the same correction start point for any luminance signal or only the difference between the value of a luminance signal at an instant and the correction start point.

A set of gamma reference voltage applied in a conventional LCD is provided with a set of resistors in serial. Thus, only one set of gamma reference voltage is provided to one or more source driver ICs of a display, which causes the image not to be corrected with the characteristics of a dynamic frame. In order to enhance the qualities of image display, the technology of dynamic contrast is implemented. However, the over process by the technology of dynamic contrast may cause some specific images less natural.

### SUMMARY OF THE INVENTION

In order to solve the problems mentioned above, the present invention provides a process method of image data for liquid crystal display. The data with non-linear characteristics is filtered for enhancing the data with linear characteristics displayed more natural.

One of objects of the present invention is to provide a process method of modifying contrast intensity of an image displayed by liquid crystal display. The histogram distribution of the image data with the large peak-to-peak difference is corrected with the lower contrast intensity.

One of objects of the present invention is to provide a process method of modifying contrast intensity of an image displayed by liquid crystal display.

One of objects of the present invention is to provide a flat display panel with the contrast enhancement of display. The data with the much amount of the specific gray-level is corrected with the lower contrast intensity for correcting histogram data well.

Accordingly, one embodiment of the present invention provides a process method for image data displayed on a liquid crystal display. An image data is inputted and acquired a histogram data thereof. The histogram data, with a threshold condition, is distinguished into a first data and a second data. Based on the first data and the threshold condition, the first data is corrected to acquire a data of contract intensity.

### BRIEF DESCRIPTION OF THE DRAWINGS

FIG. 1 is a schematic flowchart illustrating a process in accordance with a preferred embodiment of the present invention;

FIG. 2 is a schematic diagram illustrating the relationship of applied voltages and gray levels in accordance with one embodiment of present invention;

FIG. 3 is a histogram or channel histogram in accordance with one embodiment of the present invention;

FIG. 4 is a diagram illustrating the exemplary luminance analysis on a diagram of luminance distribution without equalization in accordance with one embodiment of the present invention;

FIG. 5 is a schematically block diagram illustrating the exemplary adaptive contrast technology in accordance with one embodiment of the present invention; and

FIG. 6 illustrates in the relationship of the scale and contrast in accordance with the technology of adaptive contrast correction of the present invention

### DETAILED DESCRIPTION OF THE INVENTION

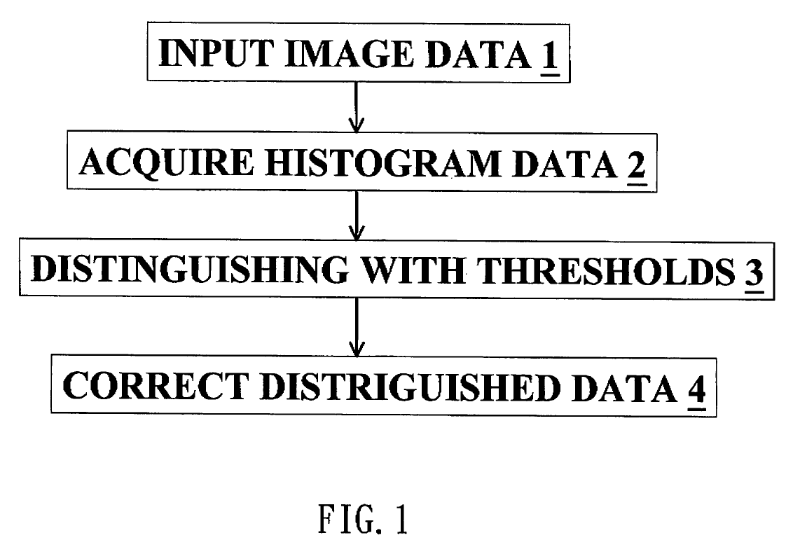

FIG. 1 is a schematic flowchart illustrating a process in accordance with a preferred embodiment of the present invention. An image data is inputted (step 1) and acquired a histogram data thereof (step 2). The histogram data, with a threshold condition, is distinguished into a first data and a second data (step 3). Based on the first data and the threshold condition, the first data is corrected to acquire a data of contract intensity (step 4). The distinguishing step with a threshold condition is illustrated in detail as follows.

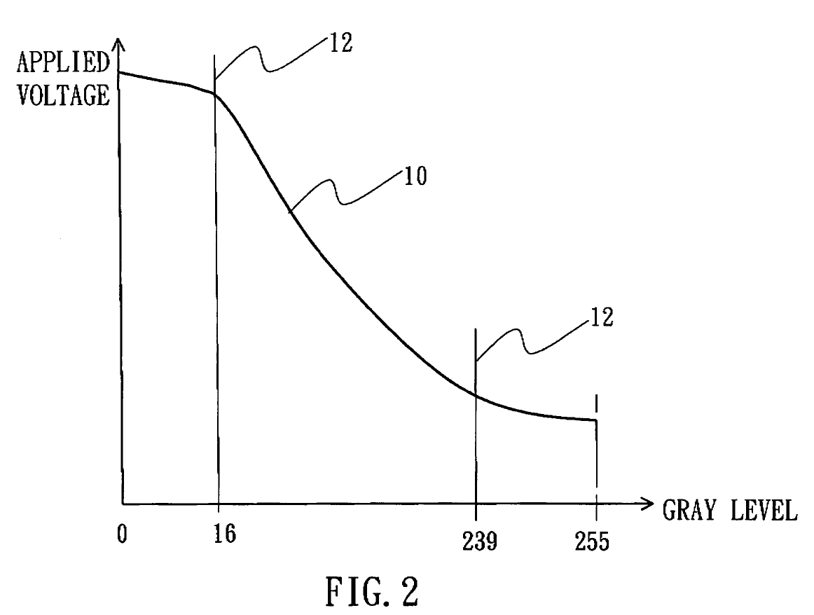

FIG. 2 is a schematic diagram illustrating the relationship of applied voltages and gray levels in accordance with one embodiment of present invention. The relationship of the applied voltages and gray levels is non-linear due to the intrinsic characteristics of liquid crystal molecules, that is, the curve of histogram voltage 10 is a non-linear curve. For most of liquid crystal molecules, regardless of configuration or anisotropic, the non-linear data may be observed on the ends of the curve of histogram voltage 10. To prevent errors for the application of pseudo-linear operation and displayed less natural, one of features of the present invention is the application of one or more threshold values. The portion of curve of histogram voltage 10 or the corresponding histogram analyzed data is filtered to separate a first data from a second data. The second data is neglected during the correction of dynamic contrast while the linear first data is remained. In the embodiment, two threshold ranges 12 are utilized to filter the second data with two discontinuous ranges of grayscales. That is, the data with the most explicitly non-linear characteristics is filtered. In a preferred embodiment, the grayscale ranges from 0 to 16 and from 239 to 255 are utilized to filter the second data, but not limited.

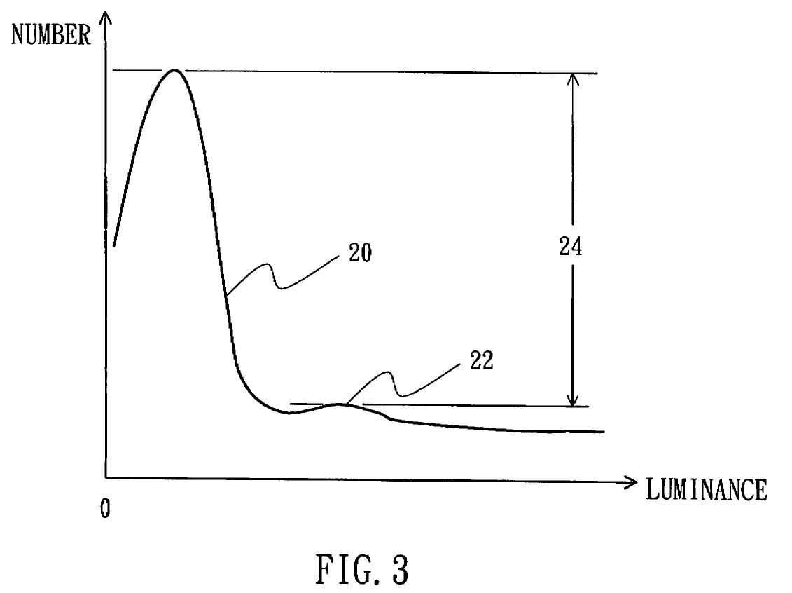

FIG. 3 is a histogram or channel histogram in accordance with one embodiment of the present invention. For some specific contents of frames, the curve of analyzed histogram 20 is with one or more zones of explicit peak-to-peak difference. With a conventional correction of dynamic contrast, the scale correction may be overdone to lower the histogram voltage corresponding to the data with the relatively low peak 22 and further cause images display less natural. According to one of features of the present invention, a threshold, such as 80%, is utilized to judge the degree of peak-to-peak difference. For example, when the peak-to-peak difference 24 of the first data is over the threshold value the first data is corrected with the lower contrast scale, such as the adjusted contrast scale of first data smaller than the one whose peak-to-peak difference is smaller than the threshold value. Thus, the image may be displayed more natural.

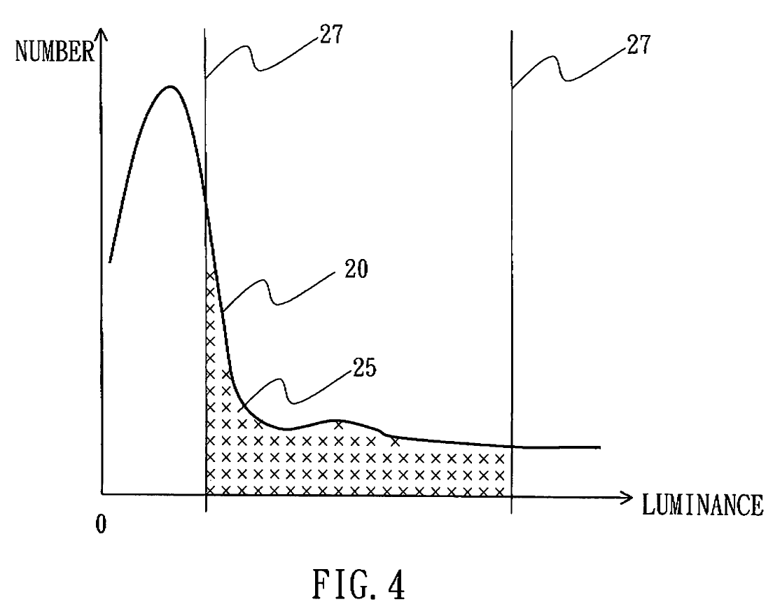

FIG. 4 is a diagram illustrating the exemplary diagram of luminance analysis without equalization in accordance with one embodiment of the present invention. In the embodiment, the area under the curve of luminance distribution 20 is determined whether the ratio is below a threshold. In a preferred embodiment, in addition to the filter of data near whole black and white in FIG. 1 with a corresponding threshold value 27, the remained data 25 is further determined whether the ratio of the remained data to the whole data is below the threshold. Once the ratio of the remained data to the whole data is blow the threshold, for example 10%, the curve of luminance distribution 20 is processed with the lower contrast intensity to enhance a displayed screen more natural. Accordingly, one of features of the present invention is to lower the contrast intensity when the ratio of the remained data is very low.

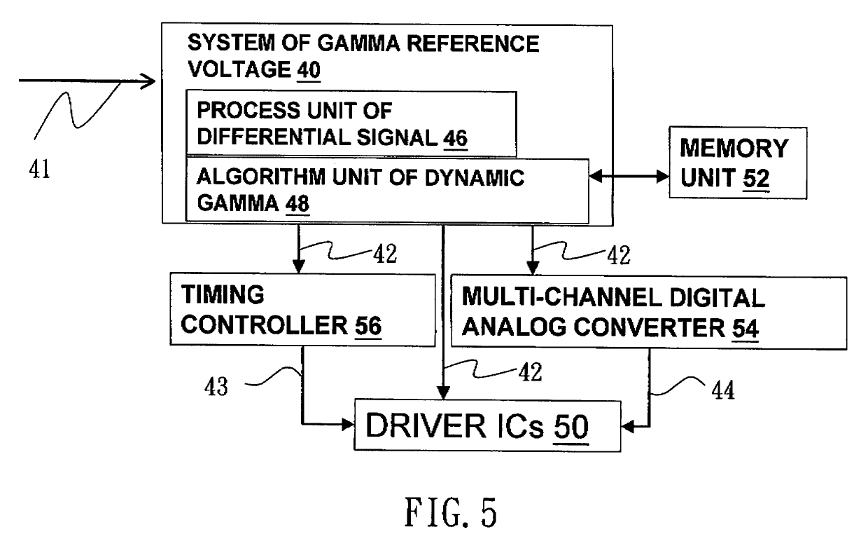

Accordingly, one of features of the present invention is to process the luminance distribution of an image with a threshold condition to make the image displayed more natural. The process of the image data is implemented by the utilization of multi-channel digital-analog converter. FIG. 5 is a schematic block diagram illustrating a system implementing the method in accordance with a preferred embodiment of the present invention. A system of gamma reference voltage 40 receives and processes an image data 41 from an exterior electrical device, such as a computer. Then the processed image data 42, a control signal 43 and a set of gamma reference voltages 44 are inputted into a driver IC 50. In one embodiment, an algorithm unit of dynamic gamma 48 is coupled to a memory unit 52 for providing the necessary space to store data and defaulted values.

In the embodiment, the image data 41 is inputted into the system of gamma reference voltage 40 and then processed in a process unit of differential signal 46. Next, the luminance distribution of the image data 41 is filtered in the algorithm unit of dynamic gamma 48. The algorithm unit of dynamic gamma 48 is configured for filtering the data of the luminance distribution for the image data 41. With the utilization of the threshold, the data with near whole black and white, the large difference of peak-to-peak, the low ratio of amount remained, or any combination thereof are filtered to ensure the image displayed more natural. Alternatively, the activation of the algorithm unit of dynamic gamma 48 may be manual to be selected by a user. The image data 42 processed by the algorithm unit of dynamic gamma 48 is then inputted into a multi-channel digital analog converter 54 for outputting the set of gamma reference voltages 44. On the other hand, a timing controller 56 outputs the control signal 43 according to the filtered image data 42 from the algorithm unit of dynamic gamma 48. The on and off statuses of the gates in the driver IC 50 are controlled by the control signal 43. In the embodiment, the timing controller 56 may be implemented by an application specific integrated circuit.

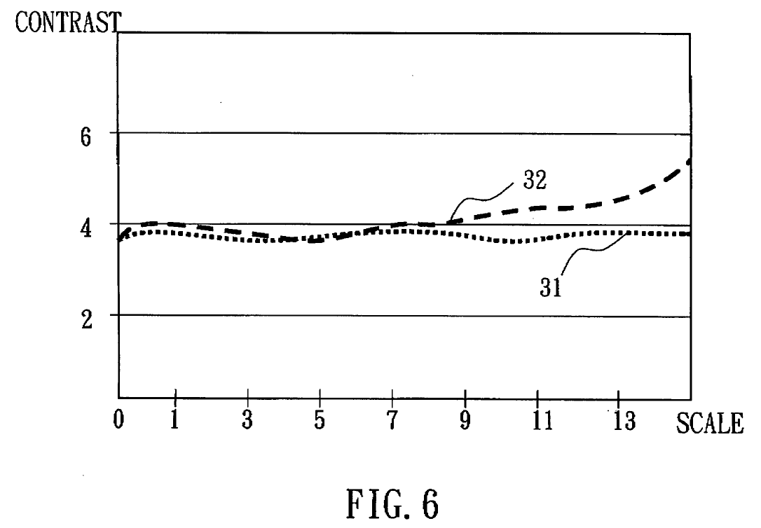

On application, a set of standard voltages is associated with the exemplary system of the present invention to be selected by the user. The set of standard voltages is used as the reference voltages for driver IC on the condition of the shut process of adaptive dynamic contract. On the other hand, the set of standard voltages may be adaptively corrected with contrast intensity (scale) processed by the technology of adaptive contrast correction to generate the adaptive set of gamma reference voltage for correcting the gamma curve. Depicted on FIG. 6, in the relationship of the scale and contrast, the curve 32 with technology of adaptive contrast correction may output the contrast in increase with the scales, compared with the curve 31 without the correction of the adaptive contrast correction.

Accordingly, the process method of modifying contrast intensity for liquid crystal display includes the following steps. The histogram data of an inputted image data is distinguished with a threshold condition into a first data and a second data. The continuous grayscale values of the first data are within discontinuous grayscale values of the second data. Based on the first data and the threshold condition, the first data is corrected to acquire a data of contract intensity.

Although the present invention has been explained in relation to its preferred embodiment, it is to be understood that other modifications and variation can be made without departing the spirit and scope of the invention as hereafter claimed.

What is claimed is:

1. A process method for image data displayed on a liquid crystal display, the process method comprising:
inputting an image data;
acquiring a histogram data of said image data;
distinguishing said histogram data, with a threshold condition, into a first data and a second data; and
correcting, based on said first data and said threshold condition, said first data to acquire a data of contract intensity.

2. The process method according to claim 1, wherein said threshold condition comprises two grayscale ranges, and said first data is out of said two grayscale ranges.

3. The process method according to claim 2, wherein said second data is within said two grayscale ranges.

4. The process method according to claim 2, wherein said two grayscale ranges comprise a first range of scale values from 0 to 16 and a second range of scale values from 239 to 255.

5. The process method according to claim 2, wherein the distinguishing step of threshold condition further comprises judging a ratio of said first data and said histogram data.

6. The process method according to claim 5, wherein when said ratio is lower than 10% the contrast intensity of said corrected first data is less than one when said ratio is higher than 10%.

7. The process method according to claim 2, wherein said threshold condition comprises a threshold value for distinguish a peak-to-peak difference of said first data.

8. The process method according to claim 7, wherein a contrast intensity of said first data with said peak-to-peak difference more than 80% is less than one of said first data with said peak-to-peak difference less than 80%.

9. A process method of modifying contrast intensity for liquid crystal display, the process method of modifying contrast intensity comprising:
inputting an image data;
acquiring a histogram data of said image data;
distinguishing said histogram data, with a threshold condition, into a first data and a second data, wherein a continuous grayscale values of said first data is within discontinuous grayscale values of said second data; and
correcting, based on said first data and said threshold condition, said first data to acquire a data of contract intensity.

10. The process method of modifying contrast intensity according to claim 9, wherein said discontinuous grayscale values of said second data comprise a first range of scale values from 0 to 16 and a second range of scale values from 239 to 255.

11. The process method of modifying contrast intensity according to claim 9, wherein said threshold condition further comprises configured for judging a ratio of said first data and said histogram data.

12. The process method of modifying contrast intensity according to claim 11, wherein when said ratio is lower than 10% the contrast intensity of said corrected first data is less than one when said ratio is higher than 10%.

13. The process method of modifying contrast intensity according to claim 9, wherein said threshold condition comprises a threshold value for distinguish a peak-to-peak difference of said first data.

14. The process method of modifying contrast intensity according to claim 13, wherein a contrast intensity of said first data with said peak-to-peak difference more than 80% is less than one of said first data with said peak-to-peak difference less than 80%
